(19) United States
(12) Patent Application Publication
(10) Pub. No.: US 2012/0295391 A1
(43) Pub. Date: Nov. 22, 2012

(54) METHOD OF MANUFACTURING A SOLAR CELL

(76) Inventors: Yoon-Mook KANG, Yongin-si (KR); Min-Chul Song, Yongin-si (KR); Tae-Jun Kim, Yongin-si (KR); Min-Sung Kim, Yongin-si (KR); Min-Ki Shin, Yongin-si (KR); Myung-Su Kim, Yongin-si (KR); Myeong-Woo Kim, Yongin-si (KR); Sang-Won Lee, Yongin-si (KR); Soon-Young Park, Yongin-si (KR); Heung-Kyoon Lim, Yongin-si (KR)

(21) Appl. No.: 13/309,870

(22) Filed: Dec. 2, 2011

(30) Foreign Application Priority Data
May 19, 2011 (KR) 10-2011-0047455

(51) Int. Cl. H01L 31/18

(52) U.S. Cl. 438/72; 257/E31.124

(57) ABSTRACT

A method of manufacturing a solar cell includes preparing a base substrate having a first conductive type; diffusing an impurity having a second conductive type (opposite the first conductive type) into the base substrate to form an emitter layer having a first impurity concentration on the base substrate and a by-product layer on the emitter layer; irradiating a laser beam onto the emitter layer corresponding to a first region of the base substrate to form a front contact portion having a second impurity concentration higher than the first impurity concentration; irradiating the laser beam onto the by-product layer to remove the by-product layer corresponding to the first region; removing the by-product layer from an area outside of the first region; forming an anti-reflection layer on the base substrate; forming a front electrode on the anti-reflection layer corresponding to the first region; and forming a back electrode on the base substrate.

### BACKGROUND

1. Field

The embodiments relate to a method of manufacturing a solar cell.

2. Description of the Related Art

A solar cell is a device to convert light energy into electrical energy. The solar cell is classified into a silicon solar cell, a thin film solar cell, a dye-reactive solar cell, and an organic polymer solar cell. The solar cell is used as a main or supplemental power source in various fields such as in electric appliances, artificial satellites, rockets, etc.

The solar cell includes a first semiconductor having a first conductive type and a second semiconductor having a second conductive type. The first semiconductor and the second semiconductor form a p-n junction, and hole-electron pairs are formed in the first and second semiconductors by light provided to the p-n junction. The holes and the electrons move by electric potential energy difference existing at the p-n junction, thereby generating current.

### SUMMARY

One or more embodiments may provide a method of manufacturing a solar cell including preparing a base substrate having a first conductive type; diffusing an impurity having a second conductive type into a front surface of the base substrate to form an emitter layer having a first impurity concentration on the base substrate and a by-product layer on the emitter layer, the second conductive type being opposite to the first conductive type; irradiating a laser beam onto the emitter layer corresponding to a first region of the base substrate to form a front contact portion having a second impurity concentration higher than the first impurity concentration; irradiating the laser beam onto the by-product layer to remove the by-product layer corresponding to the first region; removing the by-product layer from an area outside of the first region; forming an anti-reflection layer on the base substrate; forming a front electrode on the anti-reflection layer overlapping the first region; and forming a back electrode on a rear surface of the base substrate. Removing the by-product layer may include removing an amorphous silicon layer formed between the emitter layer and the by-product layer. The by-product layer and the amorphous silicon layer may be removed by a wet etch process. Forming of the front contact portion and removing of the by-product layer may be performed using a same laser beam in a single process.

The by-product layer may be a phosphorus silicate glass layer or a boron silicate glass layer. Forming the front electrode may includes coating a metal paste on the anti-reflection layer corresponding to the first region; and firing the metal paste. The front electrode and the back electrode may be formed in a single process.

The base substrate may be textured prior to forming the emitter layer and the by-product layer. Forming the emitter layer and the by-product layer may include firing the base substrate in a POCl₃ atmosphere.

### BRIEF DESCRIPTION OF THE DRAWINGS

Features will become apparent to those of ordinary skill in the art by describing in detail exemplary embodiments with reference to the attached drawings, in which:

FIG. 1 illustrates a cross-sectional view of a solar cell according to an exemplary embodiment; and

FIGS. 2A to 2J illustrate cross-sectional views of stages in a method of manufacturing the solar cell shown in FIG. 1.

### DETAILED DESCRIPTION

Korean Patent Application No. 10-2011-0047455, filed on May 19, 2011, in the Korean Intellectual Property Office, and entitled: “Method of Manufacturing A Solar Cell,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. It will be understood that when an element or layer is referred to as being “connected to” or “coupled to” another element or layer, it can be directly connected or coupled to the other element or layer or intervening elements or layers may be present. In contrast, when an element is referred to as being “directly connected to” or “directly coupled to” another element or layer, there are no intervening elements or layers present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be explained in detail with reference to the accompanying drawings.

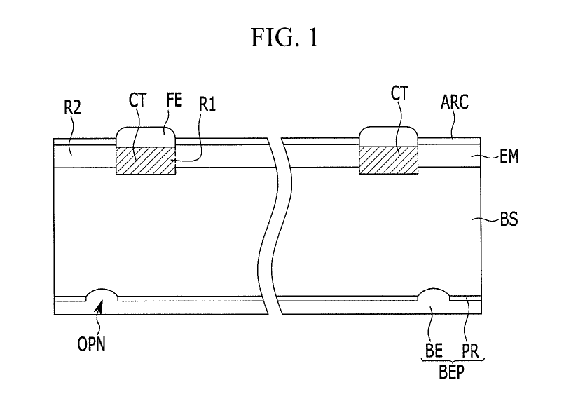

FIG. 1 illustrates a cross-sectional view showing a solar cell according to an exemplary embodiment.

Referring to FIG. 1, a solar cell may include a base substrate BS having a first conductive type, an emitter layer EM having a second conductive type opposite to the first conductive type, an anti-reflection layer ARC disposed on the emitter layer EM, a front electrode FE disposed on a front surface of the base substrate BS, and a back electrode part BEP disposed on a rear surface of the base substrate BS.

The base substrate BS may be a semiconductor layer having the first conductive type. The base substrate BS may be a silicon base substrate and include single crystalline silicon or polycrystalline silicon. The base substrate BS may have a plate-like shape including the front surface, the rear surface facing the front surface, and a side surface connecting the front surface and the rear surface. The front and rear surfaces may be wider than the side surface.

The front surface and the rear surface of the base substrate BS may be textured to have concavo-convex portions. The concavo-convex portions may be a plurality of recesses having a concavo-convex shape (e.g., a reverse pyramid shape) within top or the front surface and/or the rear surface. Due to the concavo-convex shape of the concavo-convex portions, the surface area of the solar cell, into which light is incident, may be increased, thereby enhancing light absorbance.

The emitter layer EM may be disposed on the base substrate BS to make contact with the base substrate BS. The emitter layer EM may cover the whole front surface of the base substrate BS. The emitter layer EM may include single crystalline silicon or polycrystalline silicon.

The emitter layer EM may be a semiconductor layer having the second conductive type, which is opposite to the first conductive type. The emitter layer EM may form a p-n junction with the base substrate BS. For example, when the base substrate BS has an n-conductive type, the emitter layer EM may have a p-conductive type. On the other hand, when the base substrate BS has the p-conductive type, the emitter layer EM may have the n-conductive type. In the present exemplary embodiment, the base substrate BS may have the p-conductive type and the emitter layer EM may have the n-conductive type. The emitter layer EM may be highly doped with the n-conductive type impurity such as phosphorus (P).

According to the doping concentration of the impurity, the emitter layer EM may be divided into a first region R1 and a second region R2. The second region R2 may be outside the first region R1, e.g., may be any region other than the first region R1. The doping concentration of the impurity in the first region R1 may be referred to as a first concentration and the doping concentration of the impurity in the second region R2 may be referred to as a second concentration. The first concentration of the first region R1 may be higher than the second concentration of the second region R2. The first region R1 may include a front contact portion CT, and may contact the front electrode FE. The front contact portion CT may have a high concentration of the impurity and the impurity may be deeply diffused in the front contact portion CT compared with the second region R2. As such, the front contact portion CT may have low surface resistance.

The anti-reflection layer ARC may be disposed on the emitter layer EM. The anti-reflection layer ARC may be formed of an insulating material. The anti-reflection layer ARC may include at least one of silicon oxide, silicon nitride, and silicon oxy-nitride. In addition, the anti-reflection layer ARC may have a single-layer structure or a multi-layer structure, which include at least one of the above-mentioned materials. The anti-reflection layer ARC may protect the emitter layer EM from external impacts and may prevent light from being reflected from the emitter layer EM.

The front electrode FE may be disposed on the front contact portion CT in the first region R1 to make contact with the front contact portion CT. The front electrode FE may include a metal material, such as silver, aluminum, or an alloy thereof

The back electrode part BEP may include a rear protection layer PR and a back electrode BE. The rear protection layer PR may be disposed on the rear surface of the base substrate BS. The rear protection layer PR may be provided with at least one opening OPN through which a portion of the rear surface of the base substrate BS may be exposed. The back electrode BE may be disposed on the rear protection layer PR and may make contact with the base substrate BS through the opening PR.

The back electrode BE may include a metal material, such as silver, aluminum, or an alloy thereof. Although not shown in FIG. 1, a back surface-field layer, which is highly doped with an impurity having the first conductive type, may be further formed between the base substrate BS and the back electrode BE.

Due to light from the sun, hole-electron pairs may be generated in the base substrate BS and the emitter layer EM. The electrons may move to the n-type semiconductor and the holes may move to the p-type semiconductor, thereby generating the current. For instance, when the base substrate BS is formed of the n-type semiconductor and the emitter layer EM is formed of the p-type semiconductor, the electrons may move to the back electrode BE and the holes may move to the front electrode FE to generate the current.

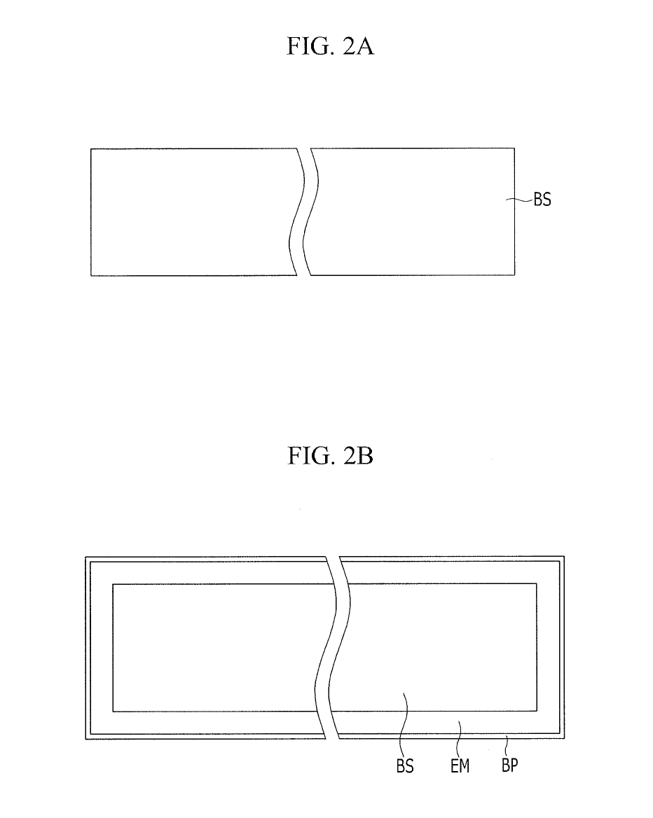

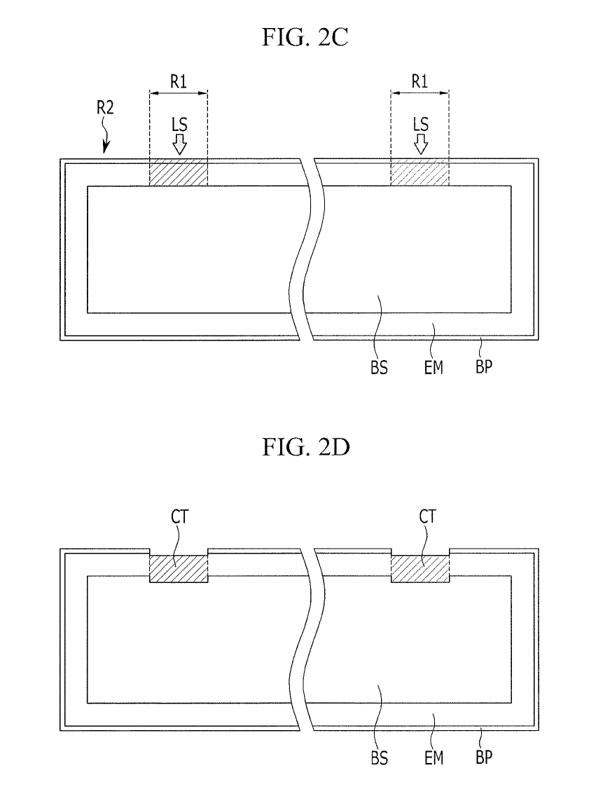

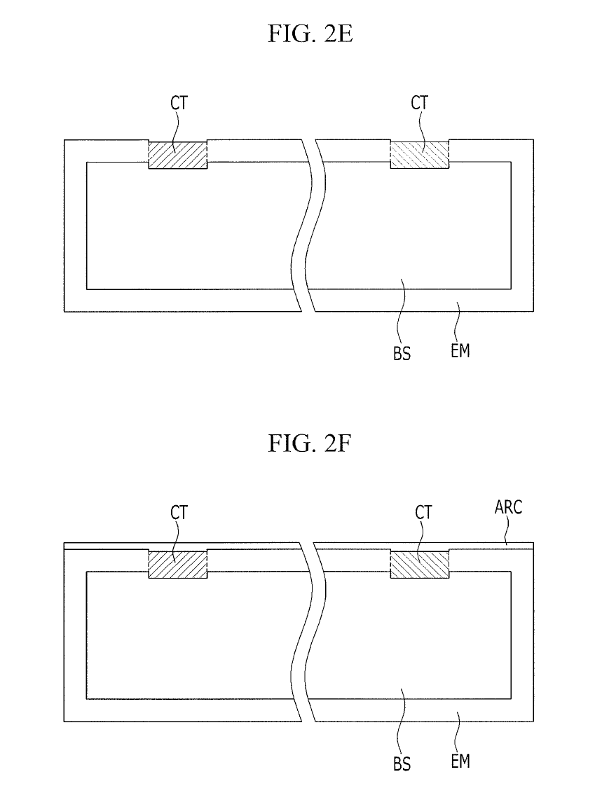

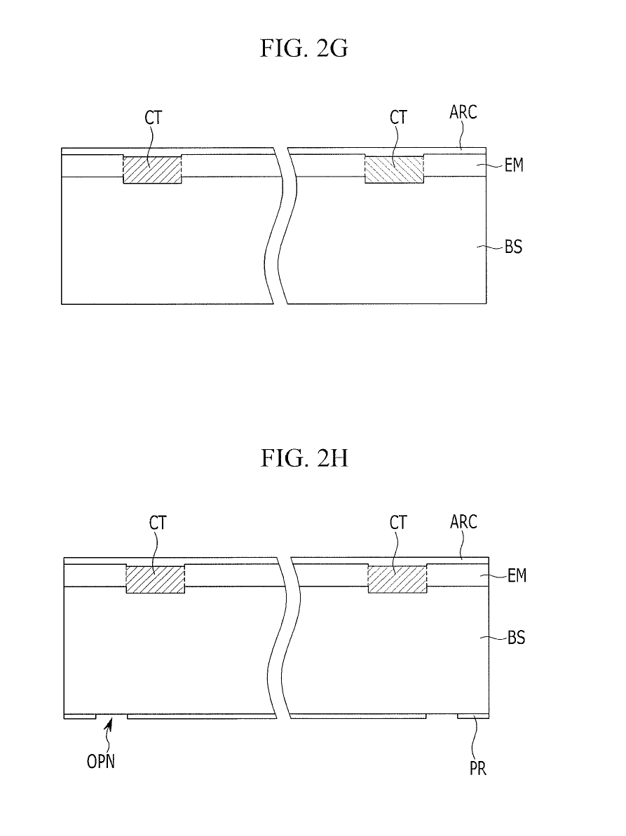

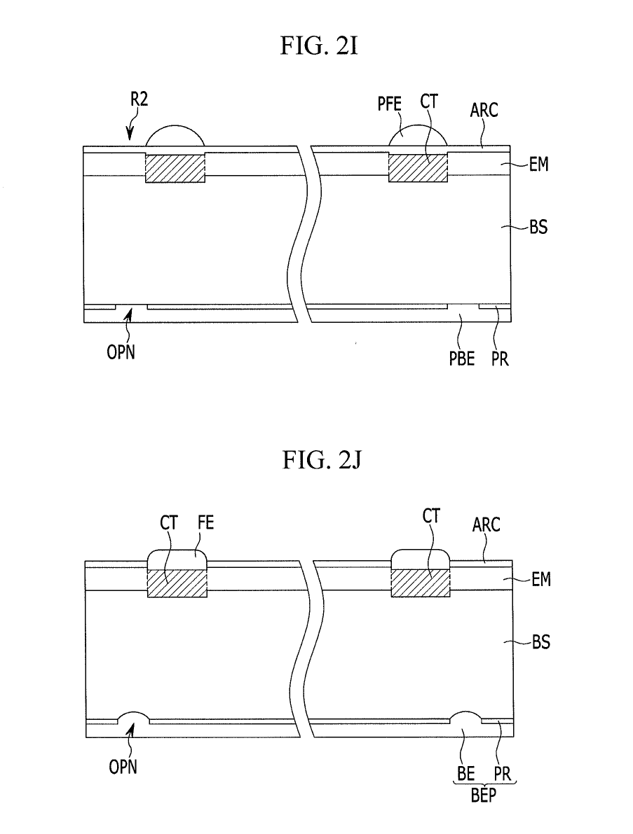

Hereinafter, the method of manufacturing the solar cell will be described in detail with reference to FIGS. 1 and 2A to 2J.

FIGS. 2A to 2J illustrate cross-sectional views of stages in a method of manufacturing the solar cell shown in FIG. 1.

As shown in FIG. 2A, the base substrate BS having the first conductive type may be prepared. The base substrate BS may be a silicon base substrate, e.g., single crystalline silicon base substrate or polycrystalline silicon base substrate. The first conductive type of the base substrate BS may be either the p-type or the n-type. The base substrate BS may be cleaned to remove a foreign substance thereon. The base substrate BS may have a plate-like shape, including the front surface and the rear surface.

Although not shown in FIG. 2A, the front and rear surfaces of the base substrate BS may be textured to have concave portions and convex portions. The concave portions of the concavo-convex portions may have, for example, a reverse pyramid shape. The concavo-convex portions may be formed by various methods, such as a plasma etching method, a mechanical scribing method, a photolithography method, a chemical etching method, etc.

Then, as shown in FIG. 2B, the emitter layer EM and a by-product layer BP may be formed on the base substrate BS.

The emitter layer EM may be doped with the impurity having the second conductive type opposite to the first conductive type. For example, when the base substrate BS has the p-conductive type, the emitter layer EM may have the n-conductive type. On the other hand, when the base substrate BS has the n-conductive type, the emitter layer EM may have the p-conductive layer.

The emitter layer EM may be formed by various methods, such as a heat diffusion method, a spray method, a printing method, etc. In the present exemplary embodiment, the emitter layer EM may be formed by using the heat diffusion method. According to the heat diffusion method, the emitter layer EM may be formed by diffusing a material of the second conductive type into the base substrate BS having the first conductive type. For example, when the base substrate BS has the p-conductive type, the emitter layer EM may be formed by loading the base substrate BS into a furnace and injecting a material of the n-conductive type (e.g., a material including phosphorus (P)) into the base substrate BS. The material including phosphorus (P) may be POCl₃. When the base substrate BS has the n-conductive type, the emitter layer EM may be formed by loading the base substrate BS into the furnace and injecting a material of the p-conductive type (e.g., a material including boron (B)) into the base substrate BS. The material including boron (B) may be BBr₃. In addition, the emitter layer EM may be formed by using an ion-implantation method that directly injects the impurity into the base substrate BS.

In this case, when the base substrate BS is exposed to a vapor of POCl₃ or BBr₃, the by-product layer BP, e.g., phosphorus silicate glass (PSG) or boron silicate glass (BSG), may be formed on the base substrate BS.

Then, as shown in FIG. 2C, a laser beam LS may be applied to the first region R1 of the emitter layer EM to selectively perform a heat treatment on the first region R1 and perform a laser ablation process on the first region R1. The first region R1 may be a region in which the front electrode FE is formed. The laser beam LS may not be irradiated onto the second region R2, in which the front electrode FE is not to be formed.

The laser beam LS may not be limited to a specific type for the heat treatment process and the laser ablation process. For instance, the laser beam LS may be output from a pulsed Nd:YAG laser having an oscillation frequency of about 20 kHz and a wavelength of about 532 nm, may be used. In addition, the laser beam LS may have a size of 5 μm×250 μm.

When the laser beam LS is selectively irradiated onto the first region R1 of the emitter layer EM, the portion of the emitter layer EM corresponding to the first region R1 and the by-product layer BP corresponding in position to the portion of the emitter layer EM in the first region are heat treated. The by-product layer BP and the emitter layer EM may be melted and re-crystallized during the heat-treatment process. Thus, the impurity in the by-product layer BP may be further diffused into the emitter layer EM. The by-product layer BP may serve as a doping precursor, so that the emitter layer EM, corresponding to the first region R1 has a doping concentration of the impurity that is higher than that of the portion of the emitter layer EM corresponding to the second region R2. The doping concentration of the impurity of the emitter layer EM corresponding to the first region R1 onto which the laser LS is irradiated is described herein as the first concentration. The doping concentration of the impurity of the emitter layer EM corresponding to the second region R2 which is not irradiated by the laser LS is described herein as the second concentration. According to some embodiments, the first concentration may be higher than the second concentration. The portion of the emitter layer EM in the first region R1 may become the front contact portion CT, which may contact the front electrode FE. The surface resistance of the front contact portion CT may become low because the front contact portion CT may have a doping concentration of impurity that is higher than that of the portion of the emitter layer EM in the second region R2.

When the laser beam LS is substantially simultaneously irradiated onto the emitter layer EM and the by-product layer BP, the laser ablation process may be performed on the by-product layer BP. The laser ablation process may include the following three processes. First, the energy absorption of the laser beam may occur at the interface between the emitter layer EM and the by-product layer BP, according to the irradiation of the laser beam LS. Second, the interface between the emitter layer EM and the by-product layer BP may be melted or vaporized by the absorbed energy and a strain may be created on the by-product layer BP. Thus, delamination of the by-product layer BP may occur. Third, when the strain on the by-product layer BP advances above a predetermined or given level, the by-product layer BP may be cracked and separated from the emitter layer EM. In the third process, the by-product layer BP may be easily removed by a wet etch process.

FIG. 2D illustrates the result of performing the heat-treatment process and the laser ablation process on the by-product layer BP corresponding to the first and second regions R1 and R2 of the emitter layer EM. As shown in FIG. 2D, the front contact portion CT may be formed in the first region R1 of the emitter layer EM, and the by-product layer BP corresponding to the first region R1 may be removed.

When the laser beam LS is irradiated in the first region R1 on the emitter layer EM and the by-product layer BP, an amorphous silicon layer (not shown) may be formed in the first region R1 at the interface between the emitter layer EM and the by-product layer BP due to the silicon that is melted by the laser beam LS. The amorphous silicon layer, formed on the surface of the emitter layer EM, may disturb the contact between the emitter layer EM and the front electrode FE, thereby degrading the contact characteristics between the emitter layer EM and the front electrode FE. The amorphous silicon layer may be removed with the by-product layer BP when the by-product layer BP is removed during the laser ablation process. Accordingly, the contact characteristics between the emitter layer EM and the front electrode FE may be improved. The amorphous silicon layer may be removed by a wet etch process.

Then, as shown in FIG. 2E, the by-product layer BP may be etched and removed from the second region R2. The etch process of removing the by-product layer BP from the second region R2 may be a wet etch process. In the present exemplary embodiment, when the by-product layer BP includes phosphorus silicate glass (PSG), the by-product layer BP may be removed using hydrofluoric acid (HF) solution. According to the present exemplary embodiment, only the by-product layer BP may be etched without etching the emitter layer EM. As such, the emitter layer EM may be prevented from being damaged.

In a conventional method for manufacturing a solar cell, an etch-back process is performed to remove an amorphous silicon layer, which also partially removes the emitter layer EM. When the emitter layer EM is etched during this process, the surface resistance of the emitter layer EM increases.

According to embodiments, however, when the by-product layer BP is selectively heat-treated in the first region R1 using the laser beam LS, the amorphous silicon layer may be formed between the emitter layer EM and the by-product layer BP in the first region R1. The portion of the by-product layer BP corresponding to the first region and the amorphous silicon layer may be removed together, prior to removal of the by-product layer BP in the second region R2. Because formation of the amorphous silicon layer is restricted to the first region R1, an additional etch back process to remove the amorphous silicon layer is not needed. As such, an additional process to remove the amorphous silicon layer, which may result in etching the emitter layer EM, may be omitted. Since additional etching of the emitter layer EM may be avoided, the low surface resistance of the emitter layer EM may be maintained.

Referring to FIG. 2G, the anti-reflection layer ARC may be formed over the base substrate BS. The anti-reflection layer ARC may be formed on the emitter layer EM at a position corresponding to the front surface of the base substrate BS. The anti-reflection layer ARC may be formed by a chemical vapor deposition (CVD) method using an insulating material. The anti-reflection layer ARC may have a single-layer or multi-layer structure and may include at least one of silicon oxide, silicon nitride, and silicon oxy-nitride.

Then, as shown in FIG. 2H, the emitter layer EM on the rear surface and the side surface of the base substrate BS may be removed by a wet etch process using the anti-reflection layer ARC as an etch mask.

Referring to FIG. 2I, the rear protection layer PR may cover the rear surface of the base substrate BS. The rear protection layer PR may be formed by using at least one of aluminum oxide (AlOx), aluminum nitride (AlN), silicon oxide (SiOx), silicon nitride (SiNx), and silicon oxy-nitride (SiON). The rear protection layer PR may include the opening OPN to expose a portion of the rear surface of the base substrate BS. The opening OPN may form part of the back electrode BE.

Then, as shown in FIG. 2J, the front electrode FE may be formed to contact the emitter layer EM on the front surface of the base substrate BS. In addition, the back electrode BE may be on the rear surface of the base substrate BS.

In order to form the front electrode FE, a first metal paste PFE may be formed on the anti-reflection layer ARC. The first metal paste PFE may be formed on the anti-reflection layer ARC by a printing method. The first metal paste PFE may include various metal powders, such as silver, aluminum, silver/aluminum, titanium/palladium/silver, etc. The first metal paste PFE may be dried for a predetermined time. The base substrate BS on which the first metal paste PFE is formed may then be fired in the furnace. Thus, impurities in the first metal paste PFE may be diffused into the anti-reflection layer ARC. As a result, the first metal paste PFE may be converted to the front electrode FE.

According to another embodiment, although not shown in figures, the front electrode FE may be formed by removing a portion of the anti-reflection layer ARC to expose a portion of the emitter layer EM and forming the first metal paste PFE on the exposed emitter layer EM. The first metal paste PFE may be printed on the exposed emitter layer EM, dried for a predetermined time, and fired in the furnace, thereby converting the first metal paste PFE into the front electrode FE.

In order to form the back electrode BE, a second metal paste PBE may be formed on the rear protection layer PR. The second metal paste PBE may include various metal powders, such as silver, aluminum, silver/aluminum, titanium/palladium/silver, etc., and the second metal paste PBE may include different powders from those of the first metal paste PFE. For instance, the second metal paste PBE may include aluminum powder, which may facilitate the back electrode BE to serve as a reflection layer for reflecting light when the second metal paste PBE is converted into the back electrode BE.

The second metal paste PBE may be formed by a printing method. The second metal paste PBE may be dried for a predetermined time. The base substrate BS on which the second metal past PBE may be formed, may then be fired in the furnace, and thereby, facilitate diffusion of impurities in the second metal paste PBE into the base substrate BS. The dried second metal paste PBE may form the rear surface BE.

Although not shown in the figures, a back surface-field layer, which may be highly doped with the impurity having the first conductive type, may be formed between the back electrode BE and the base substrate BS. The back surface-field layer may reduce recombination of electrons generated by the light.

The process of forming the front electrode FE and the process of forming the back electrode BE may be separately performed from each other, or may be performed in a single process. In particular, once the metal paste is formed on the exposed emitter layer EM and the exposed base substrate BS and the base substrate BS is fired, the front electrode FE may be substantially simultaneously formed with the back electrode BE.

As described above, the amorphous silicon layer may be easily removed and an additional etch process of the emitter layer may be omitted. Thus, the manufacturing process or the manufacturing method of the solar cell may be simplified, which may reduce associated manufacturing time and manufacturing costs. In addition, since additional etching of the emitter layer is not needed, the emitter layer of the solar cell according to embodiments may have relatively low surface resistance when compared to that of the conventional solar cell.

One or more embodiments may provide a method of manufacturing a solar cell, capable of simplifying a manufacturing process and reducing a manufacturing cost.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of manufacturing a solar cell comprising:
preparing a base substrate having a first conductive type;
diffusing an impurity having a second conductive type into a front surface of the base substrate to form an emitter layer having a first impurity concentration on the base substrate and a by-product layer on the emitter layer, the second conductive type being opposite to the first conductive type;
irradiating a laser beam onto the emitter layer corresponding to a first region of the base substrate to form a front contact portion having a second impurity concentration higher than the first impurity concentration;
irradiating the laser beam onto the by-product layer to remove the by-product layer corresponding to the first region;
removing the by-product layer from an area outside of the first region;
forming an anti-reflection layer on the base substrate;
forming a front electrode on the anti-reflection layer overlapping the first region; and
forming a back electrode on a rear surface of the base substrate.

2. The method as claimed in claim 1, wherein removing the by-product layer includes removing an amorphous silicon layer formed between the emitter layer and the by-product layer.

3. The method as claimed in claim 2, wherein the by-product layer and the amorphous silicon layer are removed by a wet etch process.

4. The method as claimed in claim 1, wherein forming the front contact portion and removing the by-product layer are performed using the same laser beam in a single process.

5. The method as claimed in claim 1, wherein the by-product layer is a phosphorus silicate glass layer or a boron silicate glass layer.

6. The method as claimed in claim 1, wherein forming the front electrode includes:
coating a metal paste on the anti-reflection layer corresponding to the first region; and
firing the metal paste.

7. The method as claimed in claim 6, wherein forming the back electrode includes:
forming a rear protection layer on the rear surface of the base substrate;
removing the rear protection layer from a second region of the base substrate;
coating the metal paste on the rear surface of the base substrate corresponding to the second region; and
firing the metal paste.

8. The method as claimed in claim 7, wherein the front electrode and the back electrode are formed in a single process.

9. The method as claimed in claim 1, further comprising texturing the base substrate prior to forming the emitter layer and the by-product layer.

10. The method as claimed in claim 1, wherein forming the emitter layer and the by-product layer includes firing the base substrate in a POCl₃ atmosphere.
